(19) United States
(12) Patent Application Publication
(10) Pub. No.: US 2026/0260845 A1
(43) Pub. Date: Sep. 3, 2026

(54) Charged Particle Beam Device

(71) Applicant: Hitachi High-Tech Corporation, Minato-ku, Tokyo (JP)

(72) Inventors: Takashi KUBO, Tokyo (JP); Minoru SAKAMAKI, Tokyo (JP); Hiroshi MORITA, Tokyo (JP)

(21) Appl. No.: 18/876,064

(22) PCT Filed: Jul. 20, 2022
(86) PCT No.: PCT/JP2022/028259

§ 371 Date: Dec. 17, 2024

(51) Int. Cl. H01J 37/248; H01J 37/26

(52) U.S. Cl. CPC H01J 37/248; H01J 37/265; H01J 2237/0206; H01J 2237/04735; H01J 2237/06375

(57) ABSTRACT

An object of the present invention is to provide a charged particle beam device that includes an electrode short-circuit mechanism capable of suppressing a change in a lens effect generated between acceleration electrodes during a change in acceleration voltage and is operable while applying an acceleration voltage to the electrode short-circuit mechanism. In the charged particle beam device according to the present invention, while applying an acceleration voltage to a first acceleration electrode, a potential difference between a short-circuit electrode and a first multi-stage acceleration electrode is controlled such that discharge does not occur, and the first multi-stage acceleration electrode and the short-circuit electrode that have the above-described potential difference are connected to each other (refer to FIG. 1).

### TECHNICAL FIELD

The present invention relates to an electrode short-circuit mechanism in a charged particle beam device.

### BACKGROUND ART

An electron gun mounted on an electron microscope includes an acceleration electrode that applies predetermined energy (hereinafter, referred to as an acceleration voltage) to electrons generated from an electron source. A device that applies a high acceleration voltage (for example, an acceleration voltage of 200 kV or higher) applies the energy to the electrons stepwise using a plurality of multi-stage acceleration electrodes disposed with voltage divider resistors interposed therebetween.

In the electron gun, when the acceleration voltage is changed, a lens effect generated between the multi-stage acceleration electrodes changes. In particular, when the acceleration voltage is set to be low, the lens effect is weakened. Therefore, an aberration coefficient generated in the electron gun tends to increase, which is a factor decreasing the performance of the electron microscope.

PTL 1 describes a method of short-circuiting any electrode among multi-stage acceleration electrodes depending on a set acceleration voltage to suppress a change in a lens effect during a change in acceleration voltage.

PTL 2 describes a method of suppressing a change in a lens effect during a change in acceleration voltage by adding a new control power supply at an acceleration voltage potential and changing potentials of multi-stage acceleration electrodes using the new control power supply.

### CITATION LIST

### Patent Literature

PTL 1: JPH07-040478B
PTL 2: JP2019-139964A

### SUMMARY OF INVENTION

### Technical Problem

In an electron microscope described in PTL 1, when a multi-stage changeover switch is operated during a change in acceleration voltage, application of an acceleration voltage needs to be stopped. When the application of the acceleration voltage is stopped, a certain period of time is required until the electron gun stably operates after applying an acceleration voltage again. In particular, in a Schottky electron gun, a decrease in heating temperature of an electron source needs to be executed together with the stop operation. Therefore, a period of time required until the electron gun operates stably further increases.

PTL 2 describes a method of suppressing a change in a lens effect generated between acceleration electrodes during a change in acceleration voltage without stopping an acceleration voltage. However, to implement the method, it is necessary to newly add a control power supply at an acceleration voltage potential and to provide a structure for supplying the voltage controlled by the control power supply to the acceleration electrode. The newly added control power supply needs to maintain a potential of the acceleration electrode at a certain value during the use of the electron microscope, and thus requires a high stability. The structure for supplying the voltage controlled by the newly added control power supply to the acceleration electrode is always incorporated into the device. Therefore, to prevent dielectric breakdown with a structure having another potential even when a high acceleration voltage is applied, an insulating structure compatible with high voltage needs to be provided. Accordingly, to implement PTL 2, an existing electron gun structure needs to be changed significantly, and it is considered that complication of the structure causes an increase in manufacturing cost and an increase in discharge risk of a voltage resistance structure.

The present invention has been made considering the above-described problems, and an object thereof is to provide a charged particle beam device that includes an electrode short-circuit mechanism capable of suppressing a change in a lens effect generated between acceleration electrodes during a change in acceleration voltage and is operable while applying an acceleration voltage to the electrode short-circuit mechanism.

### Solution to Problem

In the charged particle beam device according to the present invention, while applying an acceleration voltage to a first acceleration electrode, a potential difference between a short-circuit electrode and a first multi-stage acceleration electrode is controlled such that discharge does not occur, and the first multi-stage acceleration electrode and the short-circuit electrode having the potential difference are connected to each other.

### Advantageous Effects of Invention

The charged particle beam device according to the present invention includes an electrode short-circuit mechanism capable of suppressing a change in a lens effect generated between acceleration electrodes during a change in acceleration voltage, and is operable while applying an acceleration voltage to the electrode short-circuit mechanism. As a result, the acceleration voltage can be changed within a short period of time without a decrease in a performance of an electron gun, and an operability of an electron microscope can be significantly improved.

### BRIEF DESCRIPTION OF DRAWINGS

FIG. 1 is a configuration diagram illustrating an electron microscope 1 according to a first embodiment.

FIG. 2 is an operation example when the electron microscope 1 transitions from a high acceleration voltage observation state to a low acceleration voltage observation state.

FIG. 3 is a diagram illustrating a control flow of an acceleration voltage switching state through which the electron microscope 1 passes when switching from the high acceleration voltage observation state to the low acceleration voltage observation state.

FIG. 4 is a configuration diagram illustrating the periphery of a short-circuit electrode power supply 108 according to the first embodiment.

FIG. 5 is a circuit diagram when each of resistance values of a voltage divider resistor group 103 is R2.

FIG. 6 is a flowchart illustrating the details of Step 307.

FIG. 7 is a configuration diagram illustrating an electron microscope 1 according to a second embodiment.

FIG. 8 is a configuration diagram illustrating the periphery of a short-circuit electrode 107 according to the second embodiment.

FIG. 9 is a diagram illustrating a control flow of an acceleration voltage switching state through which the electron microscope 1 passes when switching from a high acceleration voltage observation state to a low acceleration voltage observation state.

FIG. 10 is a simulation result of an electron beam trajectory.

### DESCRIPTION OF EMBODIMENTS

### First Embodiment

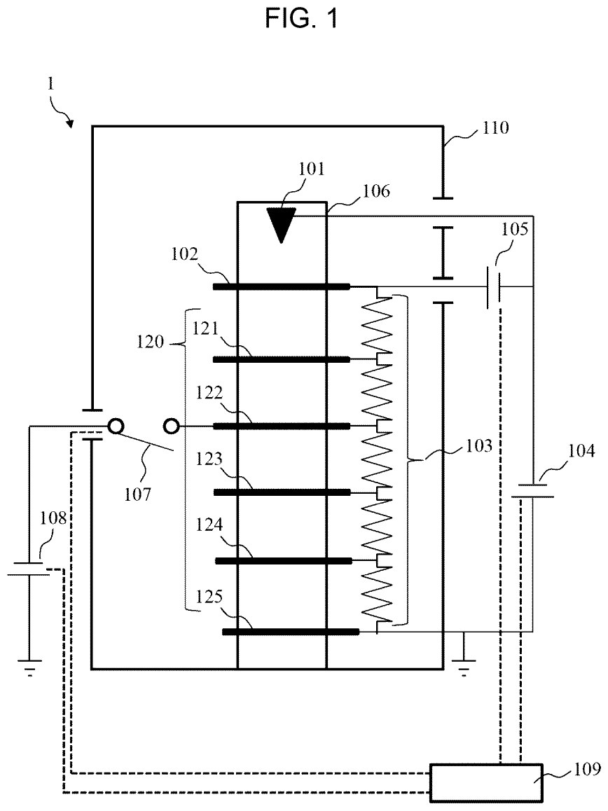

FIG. 1 is a configuration diagram illustrating an electron microscope 1 according to a first embodiment of the present invention. For convenience of description, only a peripheral portion of an electron source 101 is illustrated. The electron microscope 1 includes the following components: the electron source 101 configured to generate electrons; a first acceleration electrode 102 to which a first acceleration voltage for accelerating the electrons emitted from the electron source 101 is applied; a voltage divider resistor group 103 positioned in a rear stage of the first acceleration electrode 102 and configured to divide a voltage between the first acceleration electrode 102 and a ground; a multi-stage acceleration electrode group 120 connected to each of voltage divider resistors; a first acceleration power supply 104 configured to supply a voltage that is applied to the electron source 101 and the first acceleration electrode 102; a second acceleration power supply 105 configured to supply a voltage that is applied to the first acceleration electrode 102 by controlling a voltage at a potential that is supplied from the first acceleration power supply 104; an acceleration tube 106 holding the electron source 101, the first acceleration electrode 102, and the multi-stage acceleration electrode group 120; a short-circuit electrode 107 configured to connect a potential of at least one electrode of multi-stage acceleration electrodes to a ground; a short-circuit electrode power supply 108 configured to supply a voltage that is applied to the short-circuit electrode 107; a control device 109 configured to control voltages that are supplied to the first acceleration power supply 104, the second acceleration power supply 105, and the short-circuit electrode power supply 108 and an operation of the short-circuit electrode 107; and an electron gun housing 110 holding the acceleration tube 106 and the short-circuit electrode 107.

In the present embodiment, acceleration electrodes configuring the multi-stage acceleration electrode group 120 are called, in ascending order of distance from the first acceleration electrode 102, as follows: a multi-stage acceleration electrode 121, a multi-stage acceleration electrode 122, a multi-stage acceleration electrode 123, a multi-stage acceleration electrode 124, and a multi-stage acceleration electrode 125. The multi-stage acceleration electrode 125 is grounded. In the present embodiment, the inside of the acceleration tube 106 is a high vacuum region (for example, the gas pressure is 1×10⁻⁶ Pa or lower), and a space between the acceleration tube 106 and the electron gun housing 110 is filled with inert gas (for example, sulfur hexafluoride) to improve a discharge voltage.

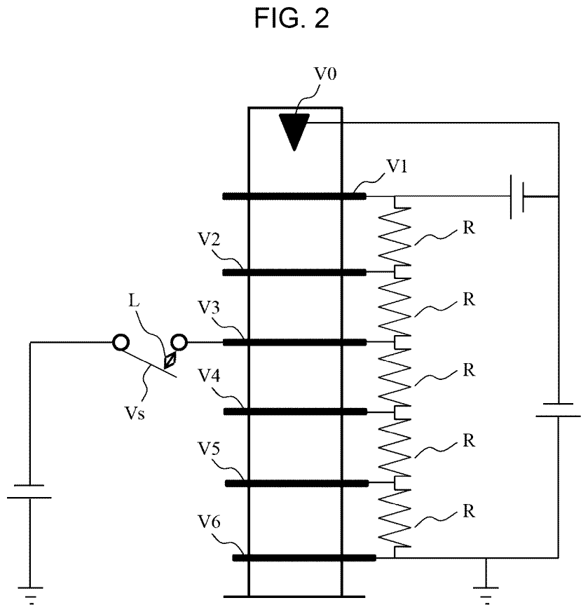

FIG. 2 is an operation example when the electron microscope 1 transitions from a high acceleration voltage observation state (for example, an acceleration voltage of 200 kV) to a low acceleration voltage observation state (for example, an acceleration voltage of 80 kV). In the present embodiment, a case where the short-circuit electrode 107 is connected to the multi-stage acceleration electrode 122 will be described as an example. In the following description, potential information of each of the structures is described, but the values described below are merely examples and do not limit the scope of the present invention.

In the high acceleration voltage observation state illustrated in FIG. 2, a potential of the electron source 101 (V0) is controlled to −200 kV by the first acceleration power supply 104. A potential difference of 20 kV relative to the electron source 101 is supplied to the first acceleration electrode 102 by the second acceleration power supply 105. As a result, the electrons are accelerated. A potential of the first acceleration electrode 102 (V1) is −180 kV because the potential difference is superimposed relative to the potential of the electron source 101 by the second acceleration power supply 105. In the present embodiment, it is assumed that resistance values R of the voltage divider resistor group 103 are set to be the same and potentials of the multi-stage acceleration electrode 121 to the multi-stage acceleration electrode 125 (V2 to V6) are set to values shown in Table 1, respectively. The short-circuit electrode power supply 108 is used for connection of the short-circuit electrode 107, and thus is stopped in the observation state. Accordingly, a potential of the short-circuit electrode 107 (Vs) is 0 kV.

TABLE 1

| | Potential | |
|---|---|---|
| V0 | −200 | kV |
| V1 | −180 | kV |
| V2 | −144 | kV |
| V3 | −108 | kV |
| V4 | −72 | kV |
| V5 | −36 | kV |

| | |
|---|---|
| V6 | 0 kV (Gnd) |
| Vs | 0 kV (Gnd) |

Based on the content described in PTL 1, to suppress a change in a lens effect generated between the acceleration electrodes during a change in acceleration voltage, a lens effect generated between the acceleration electrodes positioned on an upper stage is required to be in a state close to that before the change in acceleration voltage. The present embodiment aims to suppress changes in a lens effect generated between the first acceleration electrode 102 and the multi-stage acceleration electrode 121 and between the multi-stage acceleration electrode 121 and the multi-stage acceleration electrode 122 when the electron microscope 1 transitions from the high acceleration voltage observation state to the low acceleration voltage observation state.

Table 2 shows a potential difference between the electrodes in the high acceleration voltage observation state. Both of a potential difference between V1 and V2 and a potential difference between V2 and V3 are 36 kV. A potential difference between the multi-stage acceleration electrode 122 (V3) and the short-circuit electrode 107 is 108 kV. Here, a distance L between the multi-stage acceleration electrode 122 and the short-circuit electrode 107 is sufficiently ensured (for example, 12 mm or more), and thus discharge does not occur between the electrodes.

TABLE 2

| | Potential Difference | |
|---|---|---|
| V0-V1 | 20 | kV |
| V1-V2 | 36 | kV |
| V2-V3 | 36 | kV |
| V3-V4 | 36 | kV |
| V4-V5 | 36 | kV |
| V5-V6 | 36 | kV |
| V3-Vs | 108 | kV |

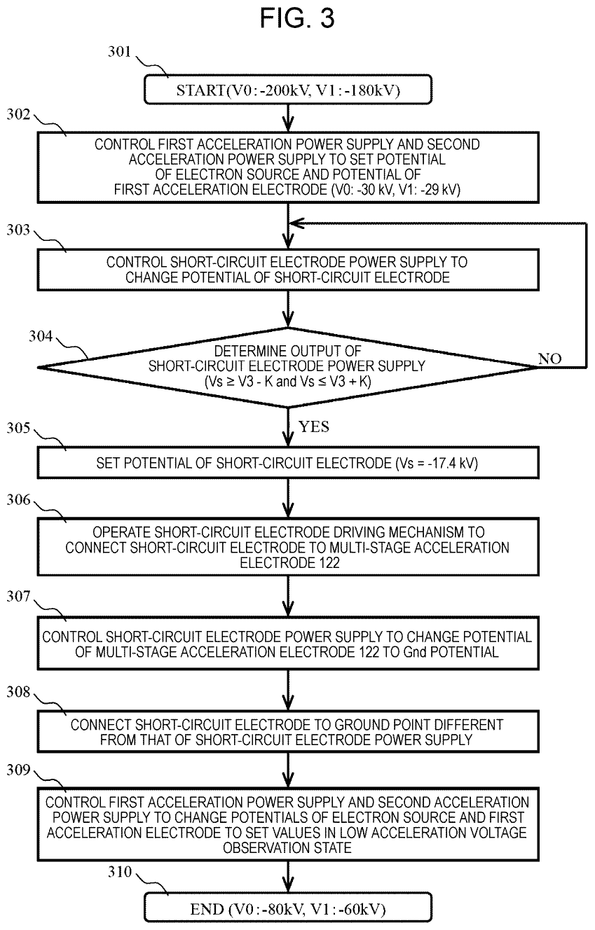

FIG. 3 is a diagram illustrating a control flow of an acceleration voltage switching state through which the electron microscope 1 passes when switching from the high acceleration voltage observation state to the low acceleration voltage observation state. In the present embodiment, to reduce a discharge risk during the operation of the short-circuit electrode 107, the electron microscope 1 passes through a potential state in S302 when switching the acceleration voltage. The present flowchart is executed by the control device 109 controlling each of the units of the electron microscope 1.

In the initial state, −200 kV is applied to the V0 potential, and −180 kV is applied to the V1 potential (Step 301). In Step 302, the control device 109 controls the first acceleration power supply 104 and the second acceleration power supply 105 to set the potential of the electron source 101 and the potential of the first acceleration electrode 102 to −30 kV and −29 kV, respectively. By such control, the potentials of the electrodes and the potential differences between the electrodes are set to the values shown in Table 3 and Table 4, respectively. −30 kV is a temporary potential that is set to temporarily reduce a potential difference from a ground potential such that excessive damage does not occur even when a trouble occurs in the periphery of the electron source 101. As long as the same effect can be exhibited, the temporarily set potential may be a value other than −30 kV. V1 may be a potential closer to the ground potential than V0.

TABLE 3

| | Potential | |
|---|---|---|
| V0 | −30 | kV |
| V1 | −29 | kV |
| V2 | −23.2 | kV |
| V3 | −17.4 | kV |
| V4 | −11.6 | kV |
| V5 | −5.8 | kV |

| | |
|---|---|
| V6 | 0 kV (Gnd) |
| Vs | 0 kV (Gnd) |

TABLE 4

| | Potential Difference | |
|---|---|---|
| V0-V1 | 1 | kV |
| V1-V2 | 5.8 | kV |
| V2-V3 | 5.8 | kV |
| V3-V4 | 5.8 | kV |
| V4-V5 | 5.8 | kV |
| V5-V6 | 5.8 | kV |
| V3-Vs | 17.4 | kV |

In Step 303, the control device 109 changes the potential set value of the short-circuit electrode 107. Step 303 is repeated until determination in Step 304 is satisfied. In Step 304, the potential difference between the short-circuit electrode 107 and the multi-stage acceleration electrode 122 is set to be within ±K. Here, K is a potential difference where discharge does not occur between the short-circuit electrode 107 and the multi-stage acceleration electrode 122 set with reference to the Paschen's curve described in “Discharge Handbook, Edited by IEEJ Discharge Handbook Publishing Committee, pp. 192” (Reference Document). As K, a value that is derived by and stored in the control device 109 in advance can be used, or K can be derived whenever the present step is executed.

In the present embodiment, the potential of the short-circuit electrode 107 is set to Vs=−17.4 kV by passing through the determination of Step 304 (Step 305). As a result, the potential difference between the short-circuit electrode 107 and the multi-stage acceleration electrode 122 is 0 kV, and even when the distance L between the two electrodes is reduced such that the two electrodes come into contact with each other, discharge does not occur. When discharge does not occur, the potential difference between the short-circuit electrode 107 and the multi-stage acceleration electrode 122 does not need to be 0 kV.

In Step 306, the control device 109 operates a short-circuit electrode driving mechanism (for example, an air cylinder) to connect the short-circuit electrode 107 to the multi-stage acceleration electrode 122. After connecting the short-circuit electrode 107 to the multi-stage acceleration electrode 122, the control device 109 controls the short-circuit electrode power supply 108 to change the potential of the multi-stage acceleration electrode 122 to the ground potential (Step 307). In the present embodiment, to reduce noise generated from the short-circuit electrode power supply 108, the control device 109 connects the short-circuit electrode 107 to a ground point different from that of the short-circuit electrode power supply 108 (Step 308).

In Step 309, the control device 109 controls the first acceleration power supply 104 and the second acceleration power supply 105 to change the potentials of the electron source 101 and the first acceleration electrode 102 to the set values in the low acceleration voltage observation state, respectively, and ends the control of the acceleration voltage switching (Step 310).

Due to the switching control of FIG. 3, the electrode short-circuit mechanism described in PTL 1 capable of suppressing a change in a lens effect generated between the acceleration electrodes during a change in acceleration voltage can be operated without stopping application of the acceleration voltage to the electron source 101. Through the present flowchart, the potentials of the electrodes and the potential differences between the electrodes are set to the values shown in Tables 5 and 6.

TABLE 5

| | Potential |
|---|---|
| V0 | −80 kV |
| V1 | −60 kV |
| V2 | −30 kV |
| V3 | 0 kV (Gnd) |
| V4 | 0 kV (Gnd) |
| V5 | 0 kV (Gnd) |
| V6 | 0 kV (Gnd) |
| Vs | 0 kV (Gnd) |

TABLE 6

| | Potential Difference | |
|---|---|---|
| V0-V1 | 20 | kV |
| V1-V2 | 30 | kV |
| V2-V3 | 30 | kV |
| V3-V4 | 0 | kV |
| V4-V5 | 0 | kV |
| V5-V6 | 0 | kV |
| V3-Vs | 0 | kV |

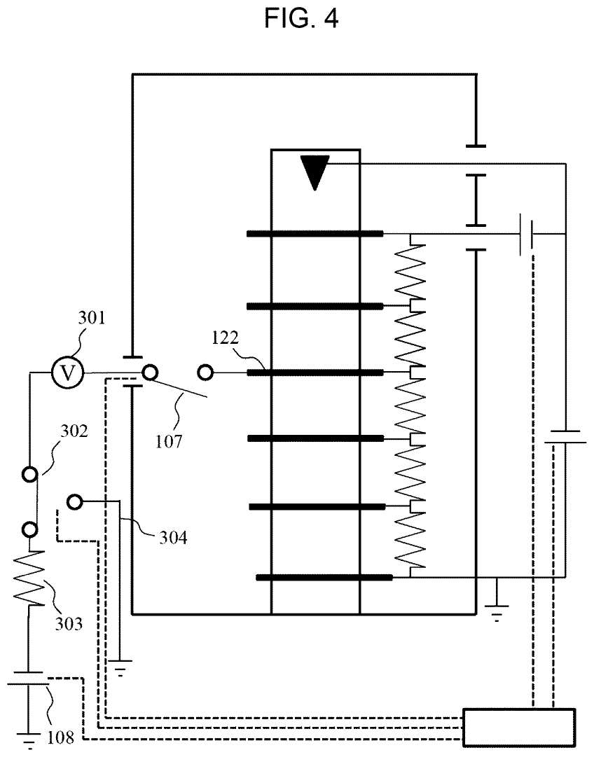

FIG. 4 is a configuration diagram illustrating the periphery of the short-circuit electrode power supply 108 according to the first embodiment. A potential measuring instrument 301, a changeover switch 302, and a protective resistor 303 are disposed between the short-circuit electrode power supply 108 and the short-circuit electrode 107. The changeover switch 302 includes three or more terminals that are connected to a structure leading to the short-circuit electrode 107, a structure leading to the short-circuit electrode power supply 108, and a structure 304 leading to the ground potential, respectively. The protective resistor (referred to as R1; for example, 1 MΩ) is provided between the changeover switch 302 and the short-circuit electrode power supply 108.

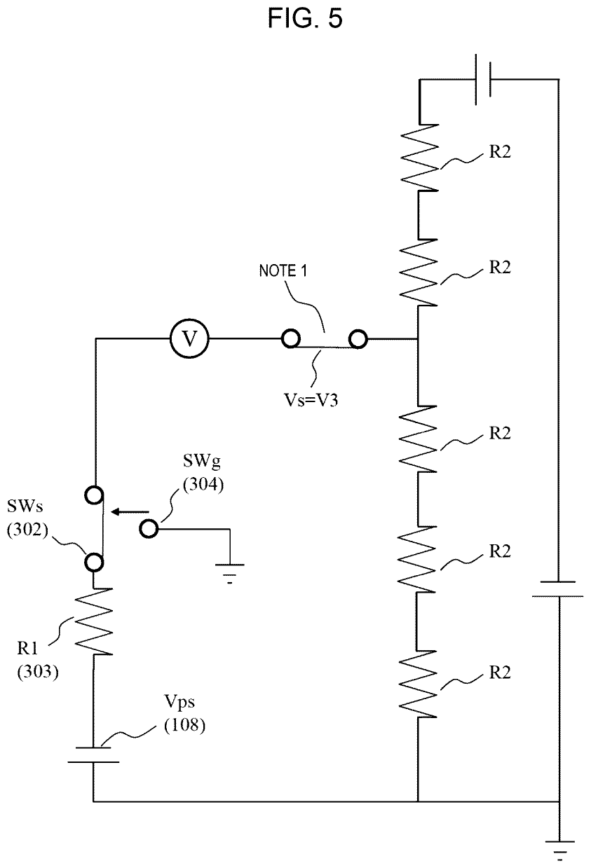

FIG. 5 is a circuit diagram when each of the resistance values of the voltage divider resistor group 103 is R2 (for example, 1.7 GΩ). Although not illustrated in the drawings, the short-circuit electrode 107 and the multi-stage acceleration electrode 122 are in a non-contact state only in Step 306 and Step 3071 described below (Note 1).

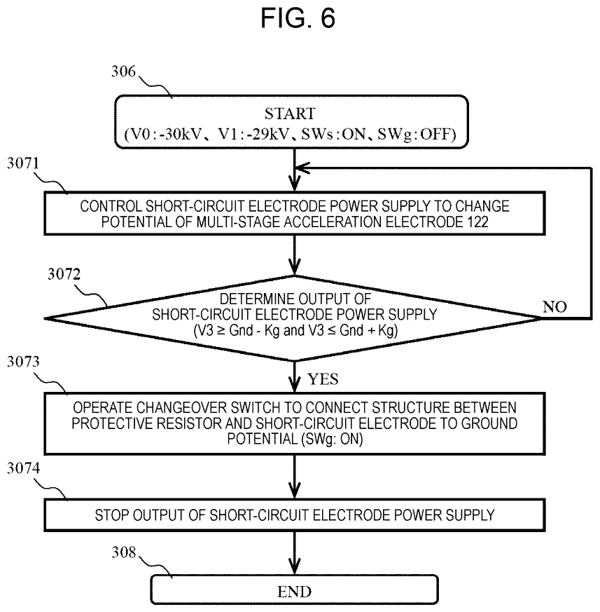

FIG. 6 is a flowchart illustrating the details of Step 307. In the initial state (Step 306), an output of the short-circuit electrode power supply 108 (Vps) is 0 kV, and the potential of the short-circuit electrode 107 (Vs) is also 0 kV. The changeover switch 302 is in a state where power flows between the short-circuit electrode 107 and the short-circuit electrode power supply 108 (SWs=ON), and is in a non-contact state with a terminal leading to the ground structure (SWg=OFF).

In Steps 3071 and 3072, the control device 109 controls the short-circuit electrode power supply 108 to change the potential of the multi-stage acceleration electrode 122 (in the present embodiment, the value of the potential measuring instrument 301 is monitored) to be within the ground potential ±a variable Kg. As the variable Kg, a potential difference where discharge does not occur between the structure of the ground potential and the short-circuit electrode 107 is derived and determined with reference to the Paschen's curve described in the reference document as in the variable K. In the present embodiment, the output of the short-circuit electrode power supply 108 (Vps) in the present step is about 8.9 V. Accordingly, the specification of the short-circuit electrode power supply 108 that is required for the present embodiment is that a voltage of about −20 kV to 10 V can be output.

The changeover switch 302 operates, for example, in the atmospheric environment. Therefore, Kg in the present flowchart is a value different from K. It is because the periphery of the electron source 101 operates, for example, in an inert gas environment.

In Step 3073, the control device 109 operates the changeover switch 302 to connect the structure between the protective resistor 303 and the short-circuit electrode 107 to the ground potential. Here, the changeover switch 302 needs to be a structure that is always connected to the protective resistor 303 because when the changeover switch 302 is opened, there is a possibility that the short-circuit electrode 107 is disconnected from the ground potential. Accordingly, in the present embodiment, by operating the structure that is the ground potential (for example, an air cylinder is used as the drive system) to come into contact with the structure between the protective resistor 303 and the short-circuit electrode 107, the switch is changed.

After setting the potential of the short-circuit electrode 107 to the ground potential, in Step 3074, the control device 109 stops the output of the short-circuit electrode power supply 108. As a result, the process of connecting the short-circuit electrode 107 to the ground point different from that of the short-circuit electrode power supply 108 (Step 307) ends.

The present flowchart also has the following significance. The short-circuit electrode power supply 108 is disposed to suppress discharge. Therefore, when it is unnecessary to suppress discharge, it is desirable that the short-circuit electrode power supply 108 is stopped not to be used for other purposes. Through the flowchart of FIG. 6, the short-circuit electrode power supply 108 is connected to the short-circuit electrode 107 and supplies power only when necessary. Therefore, the short-circuit electrode power supply 108 can be protected from an unexpected operation.

With the above-described configuration, the short-circuit electrode power supply 108 can be protected from an overcurrent generated by discharge. By connecting the structure between the protective resistor 303 and the short-circuit electrode 107 to the ground potential, the influence of a voltage drop caused by the protective resistor 303 can be ignored, and the short-circuit electrode power supply 108 can be stopped in the observation state. That is, the short-circuit electrode power supply 108 operate only when the short-circuit electrode 107 operates, and thus the power consumption of the device can be reduced. By stopping the short-circuit electrode power supply 108, noise generated from the power supply can be prevented from flowing into the device.

In the present embodiment, the potential of the short-circuit electrode 107 is set and the short-circuit electrode 107 is operated. Instead, the control device 109 may calculate an electric field between the short-circuit electrode 107 and the multi-stage acceleration electrode 122 from the distance L between the short-circuit electrode 107 and the multi-stage acceleration electrode 122 and the potential of the short-circuit electrode 107, store the result, and control the drive system of the short-circuit electrode power supply 108 and the short-circuit electrode 107 such that the electric field is in a range where discharge does not occur.

In the present embodiment, after connecting the short-circuit electrode 107, the structure between the short-circuit electrode 107 and the short-circuit electrode power supply 108 is connected to the ground point different from that of the short-circuit electrode power supply 108. However, the control by the short-circuit electrode power supply 108 may be continued.

### First Embodiment: Summary

In the electron microscope 1 according to the first embodiment, the potential of the short-circuit electrode 107 is controlled such that the potential difference between the short-circuit electrode 107 and the multi-stage acceleration electrode 122 does not cause discharge to occur, the short-circuit electrode 107 is connected to the multi-stage acceleration electrode 122, and the short-circuit electrode power supply 108 is controlled such that the potential of the short-circuit electrode 107 is the ground potential. As a result, the electrode short-circuit mechanism can be operated while applying the acceleration voltage to the electron source 101.

### Second Embodiment

In the first embodiment, the example where the potential of the short-circuit electrode 107 is controlled such that discharge does not occur using the short-circuit electrode power supply 108 has been described. In a second embodiment of the present invention, a configuration example will be described where discharge is suppressed by controlling the potential of the first acceleration electrode 102 (and a potential generated in the multi-stage acceleration electrode 122 by dividing the potential) instead of using the short-circuit electrode power supply 108.

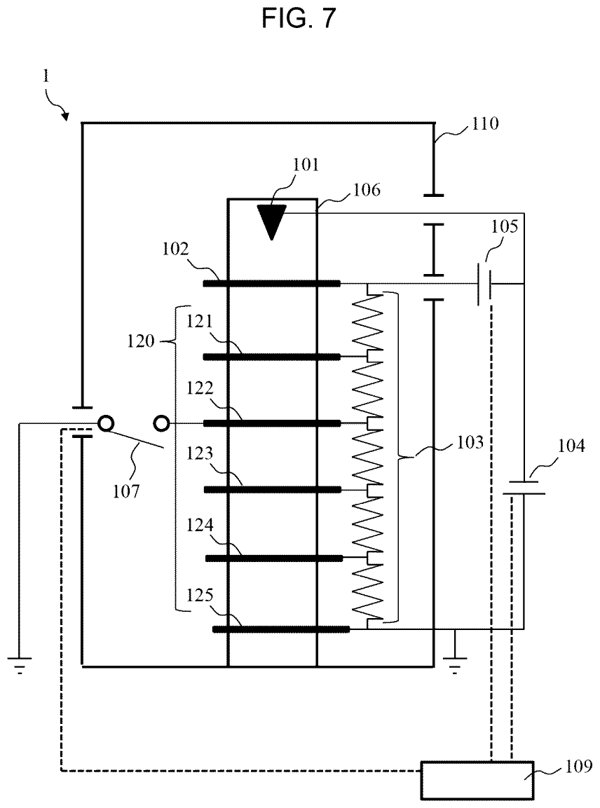

FIG. 7 is a configuration diagram illustrating the electron microscope 1 according to the second embodiment. The configuration example is different from FIG. 1 in that the short-circuit electrode power supply 108 is not provided. Since the other configurations are the same as those of FIG. 1, the differences from the first embodiment will be mainly described.

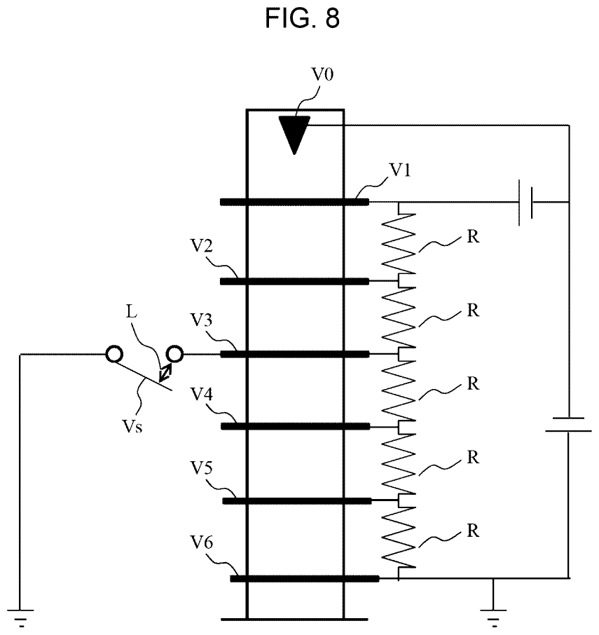

FIG. 8 is a configuration diagram illustrating the periphery of the short-circuit electrode 107 in the second embodiment. Using FIG. 8, an operation when the electron microscope 1 transitions from a high acceleration voltage observation state (for example, an acceleration voltage of 200 kV) to a low acceleration voltage observation state (for example, an acceleration voltage of 80 kV) will be described.

In the high acceleration voltage observation state illustrated in FIG. 8, the potential of the electron source 101 (V0) is controlled to −200 kV by the first acceleration power supply 104. A potential difference of 20 kV relative to the electron source 101 is supplied to the first acceleration electrode 102 by the second acceleration power supply 105. As a result, the electrons are accelerated. The potential of the first acceleration electrode 102 (V1) is −180 kV because the potential difference of 20 kV is superimposed relative to the potential of the electron source 101. The configuration of the voltage divider resistor group 103 is the same as that of the first embodiment, and the potentials of the multi-stage acceleration electrodes (V2 to V6) are set to the values shown in Table 1, respectively. Since the short-circuit electrode is connected to the ground potential, the potential of the short-circuit electrode (Vs) is 0 kV. The potential differences between the multi-stage acceleration electrodes are set to the values shown in Table 2.

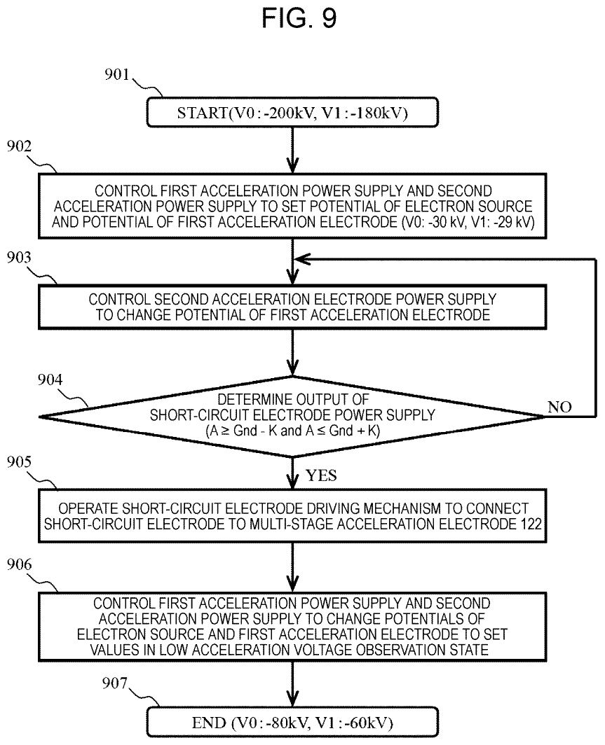

FIG. 9 is a diagram illustrating a control flow of an acceleration voltage switching state through which the electron microscope 1 passes when switching from the high acceleration voltage observation state to the low acceleration voltage observation state. In the present embodiment, to reduce a discharge risk during the operation of the short-circuit electrode 107, the electron microscope 1 passes through a potential state in S902 when switching the acceleration voltage. The present flowchart is executed by the control device 109 controlling each of the units of the electron microscope 1.

In the initial state, −200 kV is applied to the V0 potential, and −180 kV is applied to the V1 potential (Step 901). In Step 902, the control device 109 controls the first acceleration power supply 104 and the second acceleration power supply 105 to set the potential of the electron source 101 and the potential of the first acceleration electrode 102 to −30 kV and −29 kV, respectively. As a result, the potentials of the electrodes and the potential differences between the electrodes are set to the values shown in Table 3 and Table 4, respectively.

In Step 903, the control device 109 controls the second acceleration power supply 105 to change the potential of the first acceleration electrode 102. The potential change of the first acceleration electrode 102 is repeated until determination in Step 904 is satisfied. In Step 904, a value A shown in Expression 1 below is within the ground potential ±variable K. As in the first embodiment, the variable K is a potential difference where discharge does not occur between the two electrodes in the air (for example, sulfur hexafluoride) set with reference to the Paschen's curve described in the reference document. In the present embodiment, K=0.6 kV. In Expression 1, a variable N represents the number of acceleration electrodes (for example, in the present embodiment, N=6). A variable Ns represents the number of stages of the multi-stage acceleration electrode connected to the short-circuit electrode 107 (for example, in the multi-stage acceleration electrode 122, Ns=2). A variable Ri represents a resistance value of a voltage divider resistor connected between an i-th acceleration electrode and an (i+1)-th acceleration electrode (for example, when i=3, a resistance value of a voltage divider resistor provided between the multi-stage acceleration electrode 123 and the multi-stage acceleration electrode 124).

$$A = \frac{( V0 - ( V0 - V1 ) )}{\sum {R}_{i}} {{\sum }_{i = 0}}^{( N - Ns )} {R}_{( N - i )} \qquad [ Numeral 1 ]$$

In the present embodiment, an example is described where the value A of Expression 1 is the same as a determination value Gnd−K. When the potential of the electron source (V0), the number of the acceleration electrodes (N), and the number of stages of the multi-stage acceleration electrode connected to the short-circuit electrode 107 (Ns) according to the present embodiment are put into Expression 1, for A as the result to satisfy the condition of Step 904, the potential of the first acceleration electrode 102 (V1) needs to be controlled to be within =1 kV. When A is the same as the determination value Gnd-K, the potentials and the potential differences of the electrodes are set to the values shown in Tables 7 and 8. Due to the above-described control, the potential difference between the short-circuit electrode 107 and the multi-stage acceleration electrode 122 is 0.6 kV, and even when the distance L between the two electrodes is reduced such that the two electrodes come into contact with each other, discharge does not occur.

TABLE 7

| | Potential | |
|---|---|---|
| V0 | −30 | kV |
| V1 | −1 | kV |
| V2 | −0.8 | kV |
| V3 | −0.6 | kV |
| V4 | −0.4 | kV |
| V5 | −0.2 | kV |

| | |
|---|---|
| V6 | 0 kV (Gnd) |
| Vs | 0 kV (Gnd) |

TABLE 8

| | Potential Difference | |
|---|---|---|
| V0-V1 | 29 | kV |
| V1-V2 | 0.2 | kV |
| V2-V3 | 0.2 | kV |
| V3-V4 | 0.2 | kV |
| V4-V5 | 0.2 | kV |
| V5-V6 | 0.2 | kV |
| V3-Vs | 0.6 | kV |

In Step 905, a short-circuit electrode driving mechanism (for example, an air cylinder) is operated to connect the short-circuit electrode 107 to the multi-stage acceleration electrode 122. After the short-circuit electrode 107 is connected to the multi-stage acceleration electrode 122, the first acceleration power supply 104 and the second acceleration power supply 105 are controlled to change the potentials of the electron source 101 and the first acceleration electrode 102 to the set values in the low acceleration voltage observation state, respectively, and the control of the acceleration voltage switching ends (Step 906). In Step 905 and subsequent steps, after connecting the short-circuit electrode 107 to the multi-stage acceleration electrode 122, the control device 109 executes control such that the potential of the multi-stage acceleration electrode 122 is maintained. That is, each of the units is controlled such that the potential state is maintained in the ground potential while the multi-stage acceleration electrode 122 needs to be maintained in the ground potential. For example, the connection between the short-circuit electrode 107 and the multi-stage acceleration electrode 122 may be maintained.

Due to the switching control of FIG. 9, the electrode short-circuit mechanism described in PTL 1 capable of suppressing a change in a lens effect generated between the acceleration electrodes during a change in acceleration voltage can be operated without stopping application of the acceleration voltage. Through the present flowchart, the potentials of the electrodes and the potential differences between the electrodes are set to the values shown in Tables 5 and 6.

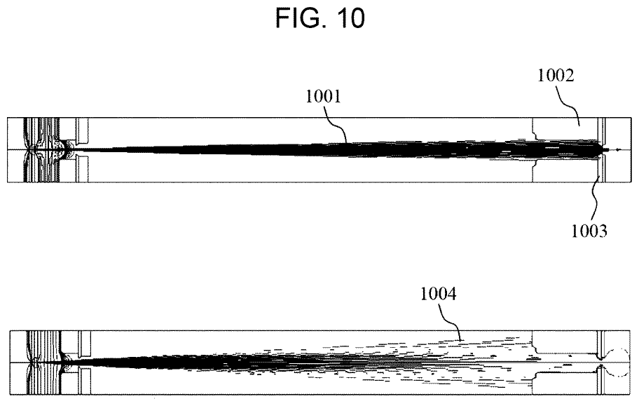

FIG. 10 is a simulation result of an electron beam trajectory. The upper stage of FIG. 10 illustrates a result when the potential of the electron source 101 (V0) is set to −30 kV in the acceleration voltage switching state. The lower stage of FIG. 10 illustrates a result when the potential of the electron source 101 (V0) is set to −10 kV. The simulation result is obtained assuming a Schottky electron source, and the lead-out voltage of the electron beam is set to 2.5 kV in both the upper stage and the lower stage. The configuration of the electron microscope 1 may be any one of the first and second embodiments.

When the potential of the electron source 101 (V0) is set to −30 kV, a trajectory 1001 of the electron beam is converged, and an electron gun aperture portion 1003 positioned in a rear stage of a structure 1002 of a ground potential provided in the acceleration tube 106 is irradiated with a large amount of the electron beam. On the other hand, when the potential of the electron source 101 (V0) is set to −10 kV, a trajectory 1004 of the electron beam tends to be dispersed, and the surface of the structure 1002 is irradiated with a large amount of the electron beam. In general, alumina is used as a material of an acceleration tube used for an electron gun. Therefore, it is not preferable that the surface of the structure 1002 is irradiated with the electron beam as in the case where the potential of the electron source 101 (V0) is set to −10 kV. It is because when alumina is irradiated with secondary electrons or dispersed primary electrons generated from the electron beam with which the surface of the structure 1002 is irradiated, a large amount of outgas is produced from alumina. The outgas is highly likely to be a factor that causes discharge or charge to occur in the acceleration tube. Therefore, it can be said that such situation is not preferable.

In the present embodiment, the potential of the first acceleration electrode 102 is set and the short-circuit electrode 107 is operated. Instead, the control device 109 may calculate an electric field between the short-circuit electrode 107 and the multi-stage acceleration electrode 122 from the distance L between the short-circuit electrode 107 and the multi-stage acceleration electrode 122 and the potential of the multi-stage acceleration electrode 122, and may control the drive system of the second acceleration power supply 105 and the short-circuit electrode 107 such that the electric field is in a range where discharge does not occur.

### <Regarding Modification Example of Present Invention>

In the above-described embodiments, the potential of the electron source 101 (V0) is set to −30 kV during the acceleration voltage switching. However, an optimum value of the potential changes depending on the structure of the electron gun or the applied voltage to each of the electrodes. Accordingly, it is preferable that a setting condition of the potential of the electron source 101 (V0) during the acceleration voltage switching is set depending on a simulation result or an experimental value of the electron beam trajectory.

In the above-described embodiments, the flow of transition from the high acceleration voltage observation state to the low acceleration voltage observation state has been described. However, a transition from the low acceleration voltage observation state to the high acceleration voltage observation state can also be executed by the present embodiments. Although the description of the process flow is not made, as in the above-described process, the short-circuit electrode power supply 108 (the first embodiment) or the second acceleration power supply 105 (the second embodiment) may be controlled such that discharge between the structures does not occur while changing the state of the changeover switch 302 and while changing the state of the short-circuit electrode 107.

In the above-described embodiments, the short-circuit electrode 107 is provided in the electron gun housing 110, but the short-circuit electrode 107 may be provided outside the electron gun housing 110.

In the above-described embodiments, the resistance values of the voltage divider resistor group 103 are all the same. However, individual resistance values may be provided.

In the above-described embodiments, the short-circuit electrode 107 is connected to the multi-stage acceleration electrode 122. However, the multi-stage acceleration electrode to which the short-circuit electrode 107 is connected may change depending on the applied acceleration voltage.

In the above-described embodiments, one short-circuit electrode 107 is provided. However, a plurality of short-circuit electrodes 107 may be provided.

In the above-described embodiments, the control device 109 can be configured by hardware such as a circuit device that implements the functions or can be configured by an arithmetic device such as a central processing unit (CPU) executing software that implements the functions.

In the above-described embodiments, the multi-stage acceleration electrode is described to be connected to the ground potential (grounded). However, even when the multi-stage acceleration electrode is connected to a reference potential other than the ground potential, the present invention is also applicable. Then, the present invention may be applied after appropriately replacing the ground potential in the above-described embodiments with the reference potential.

In the above-described embodiments, the electron microscope 1 is described as one example of the charged particle beam device. However, the present invention can also be used for a short-circuit mechanism of a multi-stage acceleration electrode in other charged particle beam devices.

### REFERENCE SIGNS LIST

101: electron source
102: first acceleration electrode
103: voltage divider resistor group
104: first acceleration power supply
105: second acceleration power supply
106: acceleration tube
107: short-circuit electrode
108: short-circuit electrode power supply
109: control device
110: electron gun housing
120: multi-stage acceleration electrode group
121: multi-stage acceleration electrode
122: multi-stage acceleration electrode
123: multi-stage acceleration electrode
124: multi-stage acceleration electrode
125: multi-stage acceleration electrode
401: potential measuring instrument
402: changeover switch
403: protective resistor

1. A charged particle beam device that irradiates a sample with a charged particle beam, the device comprising:
a charged particle source configured to emit the charged particle beam;
a first acceleration electrode to which a first acceleration voltage for accelerating the charged particle beam is applied;
a multi-stage acceleration electrode group disposed between a stage on which the sample is placed and the first acceleration electrode;
a short-circuit electrode configured to connect a first multi-stage acceleration electrode in the multi-stage acceleration electrode group to a reference potential; and
a control unit configured to control a potential of the first acceleration electrode and a potential of the multi-stage acceleration electrode group, wherein
while applying an acceleration voltage to the charged particle source, the control unit controls a potential difference between the short-circuit electrode and the first multi-stage acceleration electrode to a value where discharge does not occur, and
after connecting the first multi-stage acceleration electrode and the short-circuit electrode that have the potential difference of the value to each other, the control unit controls the potential of the first multi-stage acceleration electrode to the reference potential.

2. The charged particle beam device according to claim 1, further comprising a short-circuit electrode power supply configured to supply a voltage to the short-circuit electrode, wherein
the control unit controls the short-circuit electrode power supply such that the potential difference is set to the value, and
after connecting the first multi-stage acceleration electrode and the short-circuit electrode that have the potential difference of the value to each other, the control unit controls the short-circuit electrode power supply such that the first multi-stage acceleration electrode has the reference potential.

3. The charged particle beam device according to claim 2, further comprising a changeover switch configured to switch whether to connect the short-circuit electrode to the short-circuit electrode power supply or the reference potential, wherein
after controlling the short-circuit electrode power supply such that the first multi-stage acceleration electrode has the reference potential, the control unit operates the changeover switch such that the short-circuit electrode is connected to the reference potential.

4. The charged particle beam device according to claim 3, wherein
when the changeover switch is operated to connect the short-circuit electrode to the reference potential, the control unit controls the changeover switch to connect the short-circuit electrode to the reference potential while maintaining a connection between the short-circuit electrode and the short-circuit electrode power supply.

5. The charged particle beam device according to claim 4, wherein
when the changeover switch is operated to connect the short-circuit electrode to the reference potential, the control unit controls the short-circuit electrode power supply such that discharge does not occur in the changeover switch.

6. The charged particle beam device according to claim 2, further comprising a driving mechanism configured to change a distance between the short-circuit electrode and the first multi-stage acceleration electrode, wherein
the control unit stores a result of deriving an electric field between the short-circuit electrode and the first multi-stage acceleration electrode from the distance and a potential of the short-circuit electrode, and
the control unit controls the driving mechanism and the short-circuit electrode power supply such that the derived electric field is in a range where discharge does not occur.

7. The charged particle beam device according to claim 1, wherein
the multi-stage acceleration electrode group further includes a second multi-stage acceleration electrode between the first acceleration electrode and the first multi-stage acceleration electrode,
before connecting the first multi-stage acceleration electrode and the short-circuit electrode to each other, the control unit controls a potential difference between the first acceleration electrode and the second multi-stage acceleration electrode to a first potential difference and controls a potential difference between the second multi-stage acceleration electrode and the first multi-stage acceleration electrode to the first potential difference, and
after connecting the first multi-stage acceleration electrode and the short-circuit electrode to each other, the control unit controls a potential difference between the first acceleration electrode and the second multi-stage acceleration electrode to a second potential difference and controls a potential difference between the second multi-stage acceleration electrode and the first multi-stage acceleration electrode to the second potential difference.

8. The charged particle beam device according to claim 7, wherein
in the process of switching the first acceleration voltage between a high acceleration voltage and a low acceleration voltage, the control unit sets a potential of the first acceleration electrode to a temporary potential closer to the reference potential than the low acceleration voltage, and
the control unit executes control such that the first potential difference or the second potential difference is obtained by distributing the temporary potential between acceleration electrodes in the multi-stage acceleration electrode group.

9. The charged particle beam device according to claim 1, further comprising a voltage divider resistor configured to divide the first acceleration voltage between acceleration electrodes in the multi-stage acceleration electrode group, wherein
the control unit controls the first acceleration voltage such that a potential of the first multi-stage acceleration electrode generated by the voltage divider resistor dividing the first acceleration voltage approaches the reference potential such that discharge does not occur, and
after the potential of the first multi-stage acceleration electrode approaches the reference potential, the control unit connects the first multi-stage acceleration electrode and the short-circuit electrode to each other.

10. The charged particle beam device according to claim 1, further comprising a driving mechanism configured to change a distance between the short-circuit electrode and the first multi-stage acceleration electrode, wherein
the control unit stores a result of deriving an electric field between the short-circuit electrode and the first multi-stage acceleration electrode from the distance and a potential of the short-circuit electrode, and
the control unit controls the driving mechanism such that the derived electric field is in a range where discharge does not occur.
